(19) United States
(12) Patent Application Publication
(10) Pub. No.: US 2016/0293454 A1
(43) Pub. Date: Oct. 6, 2016

(54) SUBSTRATE PROCESSING DEVICE

(71) Applicant: TOKYO ELECTRON LIMITED, Tokyo (JP)

(72) Inventor: Tsutomu HIROKI, Nirasaki-shi (JP)

(21) Appl. No.: 14/778,134

(22) PCT Filed: Mar. 18, 2014
(86) PCT No.: PCT/JP2014/058154

§ 371 Date: Sep. 18, 2015

(30) Foreign Application Priority Data
Mar. 27, 2013 (JP) 2013-066105

(51) Int. Cl. H01L 21/67; H01J 37/32

(52) U.S. Cl. CPC H01L 21/67069; H01J 37/32009; H01J 37/3244; H01J 2237/334

(57) ABSTRACT

A substrate processing device capable of quickly increasing oxygen concentration in an area outside a substrate transfer part up to the oxygen concentration in the air while maintaining the interior of the substrate transfer part in nitrogen atmosphere is provided. In the substrate processing device, an interior of a loader module is maintained in a nitrogen atmosphere at a pressure slightly higher than the atmospheric pressure outside the substrate processing device. A blower part is disposed along a side surface of an outer upper portion of the loader module to generate an air flow along the side surface of the loader module, so that the nitrogen gas leaking from the loader module is diffused and circulated due to convection and thus, the oxygen concentration in an area outside the loader module is quickly increased up to the oxygen concentration in the air.

### TECHNICAL FIELD

The present disclosure relates to a substrate processing device for processing a substrate such as a semiconductor wafer.

### BACKGROUND

A substrate processing device is known in the art for carrying out processes such as plasma etching on a semiconductor wafer (hereinafter referred to as “wafer”). The substrate processing device includes: a loader module (substrate transfer part) disposed between a load port on which FOUPs for accommodating a plurality of semiconductor wafers are mounted and a process module (vacuum processing chamber) for carrying out plasma processing so as to load/unload the semiconductor wafers onto/from the FOUPs; a transfer module whose interior is maintained in a vacuum and which transfers the wafer to/from the process module; and a load-lock module disposed between the loader module and the transfer module. The load-lock module can be selectively switched between the atmospheric environment and the vacuum environment. In the substrate processing device, the wafer is transferred between the loader module and the transfer module through the load-lock module.

If the substrate processing device is provided with a plurality of process modules and the wafer is continuously subjected to different processes while being transferred between the plurality of process modules, there is sometimes a need that the wafer should avoid exposure to the air during a period after completion of the predetermined process before the start of the subsequent process in order to prevent oxidation or deterioration of the wafer. At this time, in order to maintain throughput of the substrate processing device, the wafer that has been subjected to a predetermined process may be temporarily returned to the FOUP. In addition, the wafer may be returned to the FOUP for the next process performed in a different substrate processing device.

The interior of the load-lock module can be returned to the atmospheric pressure by the supply of a nitrogen gas. The interior of the FOUP can be charged with a nitrogen gas. Therefore, the wafer can be isolated from the air in the load-lock module and the FOUP.

However, when the wafer which has been processed in the process module is returned to the FOUP, the wafer has to pass through the loader module. The interior of the loader module is usually kept in the atmospheric environment by the clean air supplied from a fan filter unit (FFU) installed on the ceiling. Accordingly, the wafer is exposed to the air when passing through the loader module disposed between the FOUP and the load-lock module. Under these circumstances, there has been proposed a technology which prevents the wafer in the loader module from being exposed to the air by way of supplying a nitrogen N₂ gas into the interior of the loader module (see Patent Document 1).

### PRIOR ART DOCUMENTS

### Patent Documents

Patent Document 1: Japanese Patent application publication No. 2004-311940

The interior of the loader module is maintained at a pressure higher than the pressure outside the loader module, i.e., the atmospheric pressure, for the purpose of preventing outside particles from being introduced into the loader module. For this reason, there is a possibility that the nitrogen gas supplied into the loader module may leak outside via gaps between panels or the like constituting the loader module, whereby the oxygen concentration outside the loader module is decreased endangering nearby workers due to the lack of oxygen. To cope with this problem, it can be conceivable to seal the gaps between the panels constituting the loader module, but this involves structural limitations.

### SUMMARY

The present disclosure provides a substrate processing device capable of quickly increasing oxygen concentration in an area outside a substrate transfer part up to the oxygen concentration in the air while maintaining the interior of the substrate transfer part in nitrogen atmosphere.

According to the present disclosure, provided is a substrate processing device including: a container configured to accommodate a plurality of substrates; a substrate processing part including a chamber configured to accommodate therein the substrate taken out of the container to perform a predetermined process on the substrate accommodated in the chamber; a substrate transfer part including substrate transfer means configured to transfer the substrate between the container and the substrate processing part; a nitrogen gas supplying part configured to supply a nitrogen gas into the substrate transfer part in order for an interior of the substrate transfer part to have a higher pressure than an outside of the substrate transfer part; and a blower part disposed on an external upper portion of the substrate transfer part to generate an air flow along an external side surface of the substrate transfer part.

In the substrate processing device, the blower part includes: a blade configured to create the air flow by utilizing the Coanda effect; and a fan configured to introduce air into the blade.

The blower part may include heating means configured to heat the air introduced into the blade by the fan in order for the heated air to be jetted from the blade.

A space having a predetermined gap may be defined between the blade and the external side surface of the substrate transfer part.

The substrate processing device may further include an oxygen concentration sensor disposed on the external side surface of the substrate transfer part.

The substrate processing device may further include an air supplying part configured to supply air into the substrate transfer part, wherein pressure in the interior of the substrate transfer part becomes higher than the outside of the substrate transfer part by the nitrogen gas supplied from the nitrogen supplying part and the air supplied from the air supplying part.

The container may be charged with the nitrogen gas.

According to the present disclosure, provided is a substrate processing device, including: a container configured to accommodate a plurality of substrates; a substrate processing part including a chamber configured to accommodate therein the substrate taken out of the container to perform a predetermined process on the substrate accommodated in the chamber; an intermediate transfer chamber configured to be able to accommodate the substrate taken out of the container and the substrate processed in the substrate processing part and to be switched between a nitrogen atmosphere and a vacuum atmosphere; a first substrate transfer chamber maintained in a vacuum atmosphere and having a first substrate transfer part disposed therein, the first substrate transfer part configured to transfer the substrate between the substrate processing part and the intermediate transfer chamber; a second substrate transfer chamber in which a second substrate transfer part configured to transfer the substrate between the container and the intermediate transfer chamber is disposed; a nitrogen gas supplying part configured to supply a nitrogen gas into the second substrate transfer chamber in order for an interior of the second substrate transfer chamber to be maintained in the nitrogen atmosphere at a higher pressure than an outside of the second substrate transfer chamber; and a blower part disposed on an external upper portion of the second substrate transfer chamber to generate an air flow along an external side surface of the second substrate transfer chamber, wherein the blower part includes: a blade configured to generate the air flow by utilizing the Coanda effect; and a fan configured to introduce air into the blade.

The substrate processing device may further include an air supplying part configured to supply air into the second substrate transfer chamber, wherein pressure in the interior of the second substrate transfer chamber becomes higher than the outside of the second substrate transfer chamber by the nitrogen gas supplied from the nitrogen supplying part and the air supplied from the air supplying part.

According to the present disclosure, the interior of a substrate transfer part that transfers a substrate between a container for accommodating therein a substrate and a substrate processing part for carrying out processes on the substrate is maintained in a nitrogen atmosphere. The nitrogen gas leaking outside the substrate transfer part is diffused and circulated by convection due to an air flow generated by a blower part. Thus, it is possible to prevent decrease in oxygen concentration in an outside area of the substrate transfer part and make the outside area of the substrate transfer part have substantially equal environment to the atmosphere. Therefore, workers can avoid the risk of lack of oxygen.

At this time, the air flow is generated by the blower part utilizing the Coanda effect. Thus, it is possible to more effectively diffuse and circulate the nitrogen gas leaking out of the substrate transfer part by convection. In addition, since a sufficient amount of air can be blown toward the lower portion of the substrate transfer part as well, nitrogen gas leaking from the lower portion of the substrate transfer part can be sufficiently diffused and circulated by convection, thereby suppressing a decrease in the oxygen concentration. Furthermore, the shape of the blade for generating the air flow utilizing the Coanda effect can be easily fitted into the exterior of the substrate transfer part. In addition, the blower can be easily applied to existing substrate processing devices since it is installed outside the substrate transfer part.

### BRIEF DESCRIPTION OF THE DRAWINGS

FIG. 1 is a plan view schematically showing a substrate processing device according to an embodiment of the present disclosure.

FIG. 2 is a perspective view of the substrate processing device shown in FIG. 1.

FIG. 3 is a partial cut-away sectional perspective view of a blower of the substrate processing device shown in FIG. 1.

### DETAILED DESCRIPTION

Embodiments of the present invention will now be described in detail with reference to the accompanying drawings. Herein, a semiconductor wafer (hereinafter referred to as “wafers”) is described as an example of a substrate, and a substrate process device performing plasma processing, which is one of the processes performed in a vacuum atmosphere, on the wafer is given as an example.

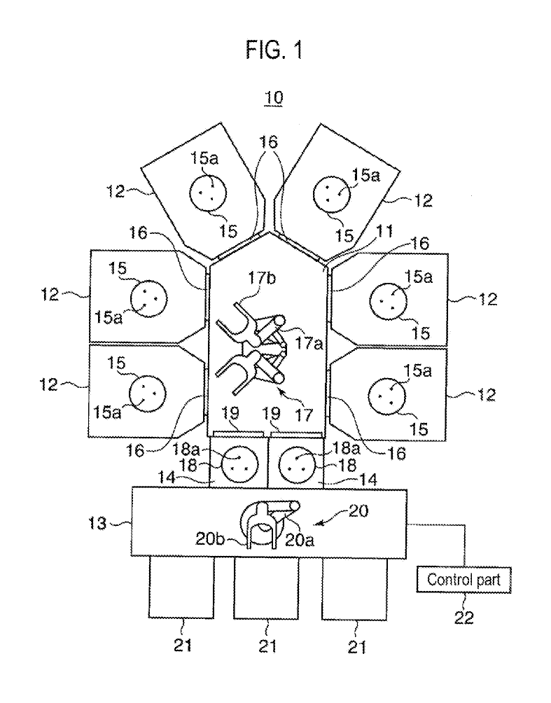

FIG. 1 is a plan view schematically showing a substrate processing device 10 according to an embodiment of the present disclosure. In the substrate processing device 10, the wafers W are subjected to plasma processing one by one. Specifically, the substrate processing device 10 includes: a transfer module (substrate transfer chamber) 11 having a roughly pentagonal shape when viewed from a plan view; six process modules (substrate process chamber) 12 circumferentially arranged around and connected to the transfer module 11; a loader module 13 disposed facing the transfer module 11; and two load-lock modules (intermediate transfer chamber) 14 disposed between the transfer module 11 and the loader module 13.

Each of the process modules 12 has a vacuum chamber. In the vacuum chamber, a cylindrical stage 15 serving as a mounting table on which the wafer W is mounted is installed. In each of the process modules 12, the vacuum chamber is set to a predetermined degree of vacuum after the wafer W is mounted on the stage 15 and processing gases are supplied into the vacuum chamber while high-frequency power is applied so as to generate plasma. By using the generated plasma, plasma processing such as etching is performed on the wafer W. The process modules 12 and the transfer module 11 are partitioned with gate valves 16.

On the stage 15 in each of the process modules 12, a plurality of thin rod-like elevation pins 15a (three elevation pins in this example) is installed such that they can protrude from the upper surface of the stage 15. The elevation pins 15a are arranged in the same circumference when view from a plan view. The elevation pins 15a protrude from the upper surface of the stage 15 to support and raise the wafer W mounted on the stage 15, and move back into the stage 15 to cause the wafer W to be mounted on the stage 15.

The interior of the transfer module 11 is maintained in the vacuum (depressurized) atmosphere. The transfer module 11 includes a first transfer part 17 having two scalar arm type transfer arms 17a. Each of the two transfer arms 17a is configured to be capable of revolving and be extensible and contractible. At the tip of each of the two transfer arms 17a, a fork (end effector) 17b on which the wafer W is loaded is installed. The first transfer part 17 can move along a guide rail (not shown) installed in the transfer module 11, and transfers the wafer W between the process modules 12 and the load-lock modules 14.

Each of the load-lock modules 14 is configured such that the internal pressure of the load-lock module 14 can vary and be switched between the vacuum atmosphere and a nitrogen atmosphere. At the transfer module 11 side of the load-lock modules 14, gate valves 19 are installed to open/close wafer loading/unloading ports, respectively. In addition, at the loader module 13 side of the load-lock modules 14, gate valves (not shown) are installed to open/close wafer loading/unloading ports, respectively. In each of the load-lock modules 14, a cylindrical stage 18 is disposed as a mounting table on which the wafer W is mounted. On the stage 18, elevation pins 18a similar to the elevation pins 15a are installed such that they can protrude from the upper surface of the stage 18.

When the wafer W is transferred from the loader module 13 to the transfer module 11, the interior of the load-lock module 14 is first maintained at a pressure equal to that of the loader module 13 by a nitrogen gas supplied into the load-lock module 14 and the load-lock module 14 receives the wafer W from the loader module 13. Then, the interior of the load-lock module 14 is depressurized to a predetermined degree of vacuum and the load-lock module 14 delivers the wafer W to the transfer module 11. On the contrary, when the wafer W is transferred from the transfer module 11 to the loader module 13, the interior of the load-lock module 14 is first maintained in a vacuum and the load-lock module 14 receives the wafer W from the transfer module 11. Then, the nitrogen gas is supplied into the load-lock module 14 to increase the internal pressure of the load-lock module 14 to a pressure equal to that of the loader module 13, and the load-lock module 14 delivers the wafer W to the loader module 13.

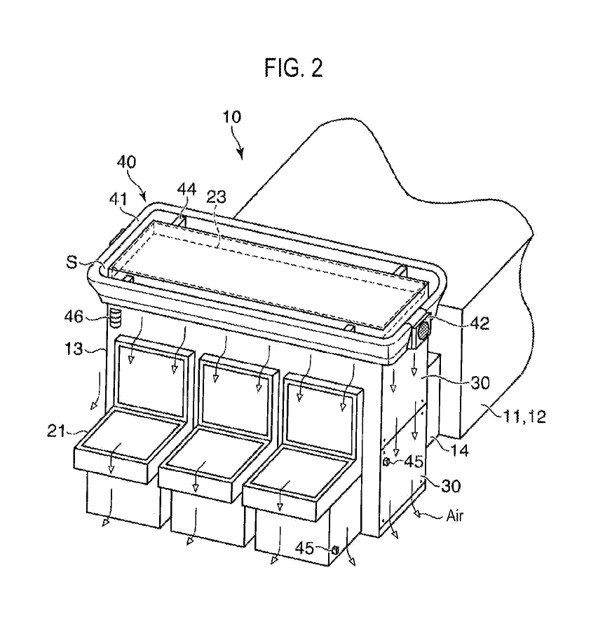

The loader module 13 is configured to have a rectangular parallelepiped chamber (see FIG. 2). The load-lock module 14 is connected to one side of the loader module 13 in the lengthwise direction. FOUP tables 21 (three FOUP tables in this example) on which FOUPs (not shown) for receiving a plurality of wafers W therein are mounted are connected to the other side of the loader module 13 in the lengthwise direction. The FOUP can maintain a state where the interior of the FOUP is charged with a nitrogen gas.

On the ceiling of the loader module 13, a nitrogen gas supplying part 23 (not shown in FIG. 1 and see FIG. 2) is installed. By the nitrogen gas supplied from the nitrogen gas supplying part 23, the interior of the loader module 13 is maintained in a nitrogen atmosphere at a pressure slightly higher than the pressure outside the substrate processing device 10. By doing so, it is possible to prevent the air and particles outside the substrate processing device 10 from being introduced into the loader module 13.

In the loader module 13, a second transfer part 20 for transferring the wafer W is disposed. The second transfer part 20 has a scalar arm type transfer arm 20a. The transfer arm 20a is configured to be movable along a guide rail (not shown) while being capable of revolving. The transfer arm 20a is also extensible and contractible. Similar to the first transfer part 17, a fork 20b is installed at the tip of the transfer arm 20a on which the wafer W is loaded. In the loader module 13, the second transfer part 20 transfers the wafer W between the FOUPs mounted on the FOUP tables 21 and the load-lock modules 14. The substrate processing device 10 is driven under the control of a control part 22.

In the substrate processing device 10, the interior of the load-lock module 14 can be maintained in the nitrogen atmosphere and the interior of the loader module 13 is also maintained in the nitrogen atmosphere. Further, the FOUPs can be charged with the nitrogen gas. Accordingly, it is possible to transfer the wafer W processed in the process modules 12 to the FOUPs with no contact between the wafer W and the air. Similarly, when the FOUPs are charged with the nitrogen gas, it is possible to transfer the wafer W from the FOUPs to the process modules 12 with no contact between the wafer W and the air.

Accordingly, in the case where, for example, a wafer W having been processed in one of the six process modules 12 needs to be transferred to the other process module 12 for the subsequent process, the wafer W should avoid contact with air until the subsequent process is started and all of the process modules for that subsequent process are in operation, the wafer W is temporarily retuned to the FOUP. Thus, the process module from which the wafer W is taken out can receive and process the next wafer W. In this manner, the wafer W which needs to avoid contact with air (oxygen, moisture, etc.) can be processed efficiently, thereby achieving high throughput of the substrate processing device 10.

In addition, even in the case where a wafer W having been subjected to a predetermined process in one of two substrate processing devices 10 needs to be processed in the other substrate processing device 10 for the subsequent process and the wafer W should avoid contact with air during a period between the previous process and the subsequent process, it is possible to transfer the wafer W processed in the process module 12 of one substrate processing device 10 to the process module 12 of the other with no contact with air.

FIG. 2 is a perspective view of the exterior of the substrate processing device 10. As described above, the interior of the loader module 13 is maintained in the nitrogen atmosphere at a pressure slightly higher than the atmospheric pressure outside the substrate processing device 10. The exterior of the loader module 13 is configured such that a plurality of panel members 30 is fixed to a frame (not shown) by screwing and so on. Sealing members such as rubber are disposed in contact surfaces between the frame and the panel members 30.

However, it is difficult to configure the exterior of the loader module 13 with no gaps between the parts. Accordingly, there is a possibility that the nitrogen gas in the interior of the loader module 13 leaks to the outside thereof through joints or the like between the panel members 30, so that the concentration of oxygen in the area outside the loader module 13 is lowered and the workers are endangered due to the lack of oxygen.

In view of this, the substrate processing device 10 includes an annular blower part 40 disposed along the side surface of the outer upper portion of the loader module 13 to generate an air flow along the side surface of the loader module 13. By the air flow, the nitrogen gas leaking from the loader module 13 is diffused and circulated due to convection. Thus, a decrease in concentration of oxygen in the area outside the loader module 13 is suppressed (the oxygen concentration is maintained at approximately 21%, which is the oxygen concentration in the air), to secure the safety of workers.

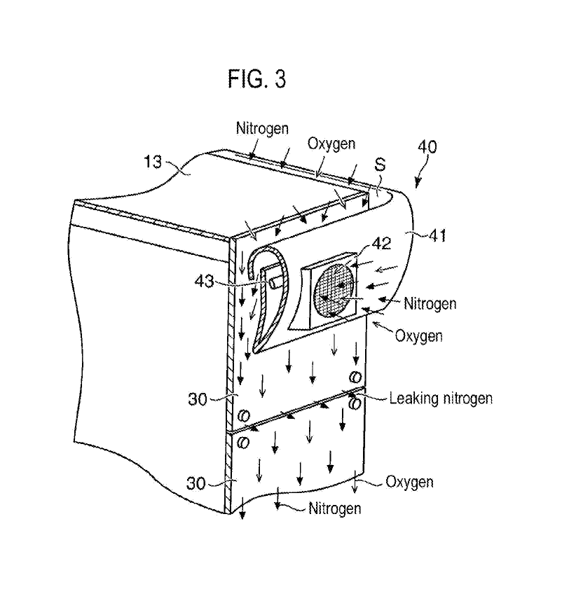

FIG. 3 is a partial cut-away sectional perspective view of the loader module 13 and the blower part 40. A blower part 40 has an annular blade 41 and a fan 42 for introducing the air into the blade 41. The blade 41 is held by a plurality of mounting metal brackets 44 such that a space S is secured between the panel members 30 constituting sidewalls of the loader module 13 and the blade 41. A heater 43 is disposed inside the blade 41.

The blade 41 is designed to have a shape which allows the air introduced by the fan 42 to jet along the sidewalls of the loader module 13 due to the Coanda effect. The fan 42 may be a propeller fan but is not limited thereto. Any type of fan may be employed as long as it can introduce the air.

Since the blower part 40 generates air flow through the Coanda effect, the air introduced from the fan 42 can flow more effectively along the sidewalls of the loader module 13. In addition, the air is introduced, by the air flow discharged from the blade 41, through the space S, defined between the panel members 30 and the blade 41, so that a larger volume of air flow can be formed.

The air flow thus generated diffuses and circulates, by convection, the nitrogen gas leaking from the joints between the panel members 30 constituting the exterior of the loader module 13. At this time, even the nitrogen gas leaking from the lower portion of the loader module 13 to the outside of loader module 13 can be diffused and circulated by convection using a sufficient amount of the air flow, together with the nitrogen gas existing near the blower part 40. Accordingly, the concentration of oxygen in the area outside the loader module 13 including portions at which the nitrogen gas leaks from the joints or the like between the panel members 30 can be quickly increased to the oxygen concentration in the air. As a result, workers can avoid the risk of a lack of oxygen.

It is desirable to dispose the heater 43 inside the blade 41 to warm up and discharge the introduced air since the expanded air accelerates the air flow discharged from the blade 41 and thus the amount of air introduced from the space S between the panel members 30 forming the loader module 13 and the blade 41 is increased. As a result, the nitrogen gas leaking from the loader module 13 can be more effectively diffused and circulated by convection.

The blower part 40 has advantages in that it can be installed in loader modules of existing substrate processing devices and the shape design and layout of the blower part 40 for fitting into an exterior having a planar portion such as the loader module 13 are easy.

As shown in FIG. 2, it is also desirable to dispose oxygen concentration sensors 45 at a plurality of locations such as the panel members 30 constituting the loader module 13 or the FOUP tables 21 to monitor variations in oxygen concentration. In this connection, it is desirable for the workers to be able to notice a sensing result by the oxygen concentration sensors 45 by using colors of a pilot lamp 46, e.g., red (indicative of low oxygen concentration; danger), yellow (indicative of slight decrease in oxygen concentration; caution), and blue (indicative of normal oxygen concentration; safe). In addition, it is desirable to attract the operator's attention using an audible alarm when the color of the pilot lamp 46 changes from blue to yellow.

Although the embodiments of the present disclosure have been described above, the present disclosure is not limited thereto. For example, although the blower part 40 is disposed such that it surrounds the outer periphery of the loader module 13 in the above-described embodiments, the blower part 40 may be configured such that portions of the blower part 40, for example, a portion existing at a frontal side, i.e., the FOUP tables 21 side, having fewer joints between panel members or a portion existing at a rear side, i.e., the load-lock modules 14 side, which workers do not usually enter, are removed.

In addition, although the configuration in which a nitrogen gas is supplied into the loader module 13 is described in the above-described embodiments, the present disclosure is not limited thereto. For example, a configuration obtainable by combining the conventional configuration in which the air is introduced into the loader module 13 by FFU with a configuration in which a nitrogen gas can be supplied into the loader module or a configuration in which the air is mixed with a nitrogen gas to generate a mixed gas having low oxygen concentration and the mixed gas is supplied by FFU, may be possible. In this configuration, the interior of the loader module 13 is maintained at a pressure higher than the outside of the loader module 13 in a state where the oxygen concentration within the loader module 13 is kept lower than that of the air. Further, the blower part 40 may also be installed in this configuration. The configuration is advantageous in that it can be implemented through simple remodeling of an existing substrate processing device. In addition, the configuration is useful when the wafer W does not need to be completely isolated from oxygen but it should avoid exposure to oxygen as much as possible. In addition, in this configuration, when the load-lock module 14 is communicated with the loader module 13, a nitrogen gas or a gas having the same composition as that supplied into the loader module 13 may be supplied into the load-lock module 14.

In addition, although a plasma processing device is described as the substrate processing device in the above-described embodiments, the present disclosure is not limited thereto. For example, the configuration of the substrate processing device of the present disclosure is useful in a film forming apparatus in which a film forming process is performed on a substrate and, after that, a baking process (heating process) is performed. In this case, the substrate can be returned to FOUPs after being taken out from a processing module without contact with the air for a predetermined period, i.e., up until the temperature of the substrate decreases to a certain degree. Although a semiconductor wafer has been described as the substrate in the above-described embodiments, the present disclosure is not limited thereto. The substrate may be a glass substrate or a ceramic substrate for a flat panel display (FPD).

This application claims the benefit of Japanese Patent Application No. 2013-066105, filed on Mar. 27, 2013, in the Japanese Patent Office, disclosure of which is incorporated herein in its entirety by reference.

### EXPLANATION OF REFERENCE NUMERALS

10: substrate processing device, 12: process module, 13: loader module, 14: load-lock module, 23: nitrogen gas supplying part, 40: blower part, 41: blade, 42: fan, 43: heater

What is claimed is:

1. A substrate processing device comprising:
a container configured to accommodate a plurality of substrates;
a substrate processing part including a chamber configured to accommodate therein the substrate taken out of the container to perform a predetermined process on the substrate accommodated in the chamber;
a substrate transfer part including substrate transfer means configured to transfer the substrate between the container and the substrate processing part;
a nitrogen gas supplying part configured to supply a nitrogen gas into the substrate transfer part in order for an interior of the substrate transfer part to have a higher pressure than an outside of the substrate transfer part; and
a blower part disposed on an external upper portion of the substrate transfer part to generate an air flow along an external side surface of the substrate transfer part.

2. The substrate processing device of claim 1, wherein the blower part comprises:
a blade configured to create the air flow by utilizing a Coanda effect; and
a fan configured to introduce air into the blade.

3. The substrate processing device of claim 2, wherein the blower part further comprises:
heating means configured to heat the air introduced into the blade by the fan in order for the heated air to be jetted from the blade.

4. The substrate processing device of claim 2, wherein a space having a predetermined gap is defined between the blade and the external side surface of the substrate transfer part.

5. The substrate processing device of claim 1, further comprising:
an oxygen concentration sensor disposed on the external side surface of the substrate transfer part.

6. The substrate processing device of claim 1, further comprising:
an air supplying part configured to supply air into the substrate transfer part, wherein pressure in the interior of the substrate transfer part becomes higher than the outside of the substrate transfer part by the nitrogen gas supplied from the nitrogen supplying part and the air supplied from the air supplying part.

7. The substrate processing device of claim 1, wherein the container is charged with the nitrogen gas.

8. A substrate processing device, comprising:
a container configured to accommodate a plurality of substrates;
a substrate processing part including a chamber configured to accommodate therein the substrate taken out of the container to perform a predetermined process on the substrate accommodated in the chamber;
an intermediate transfer chamber configured to be able to accommodate the substrate taken out of the container and the substrate processed in the substrate processing part and to be switched between a nitrogen atmosphere and a vacuum atmosphere;
a first substrate transfer chamber maintained in a vacuum atmosphere and having a first substrate transfer part disposed therein, the first substrate transfer part configured to transfer the substrate between the substrate processing part and the intermediate transfer chamber;
a second substrate transfer chamber in which a second substrate transfer part configured to transfer the substrate between the container and the intermediate transfer chamber is disposed;
a nitrogen gas supplying part configured to supply a nitrogen gas into the second substrate transfer chamber in order for an interior of the second substrate transfer chamber to be maintained in the nitrogen atmosphere at a higher pressure than an outside of the second substrate transfer chamber; and
a blower part disposed on an external upper portion of the second substrate transfer chamber to generate an air flow along an external side surface of the second substrate transfer chamber,
wherein the blower part comprises:
a blade configured to generate the air flow by utilizing a Coanda effect; and
a fan configured to introduce air into the blade.

9. The substrate processing device of claim 8, further comprising:
an air supplying part configured to supply air into the second substrate transfer chamber, wherein pressure in the interior of the second substrate transfer chamber becomes higher than the outside of the second substrate transfer chamber by the nitrogen gas supplied from the nitrogen supplying part and the air supplied from the air supplying part.
